(19) United States
(12) Patent Application Publication
(10) Pub. No.: US 2023/0143108 A1
(43) Pub. Date: May 11, 2023

(54) FURNACE AND METHOD FOR FORMING FILM

(71) Applicant: CHANGXIN MEMORY TECHNOLOGIES, INC., Hefei City (CN)

(72) Inventor: CHING-LUNG WANG, Hefei (CN)

(73) Assignee: CHANGXIN MEMORY TECHNOLOGIES, INC., Hefei City (CN)

(21) Appl. No.: 17/810,594

(22) Filed: Jul. 1, 2022

(30) Foreign Application Priority Data
Nov. 8, 2021 (CN) 202111316125.1

(51) Int. Cl. C23C 16/455; C23C 16/34; C23C 16/505; C23C 16/44; C23C 16/52

(52) U.S. Cl. CPC C23C 16/45561; C23C 16/345; C23C 16/505; C23C 16/4405; C23C 16/52

(57) ABSTRACT

A furnace includes: a reaction chamber; a wafer boat assembly comprising multiple wafer boats each for bearing a substrate and an input pipeline assembly configured to introduce a gas are arranged in the reaction chamber; the introduced gas at least includes: silicon-containing reaction gas, nitrogen-containing reaction gas, impurity removal reaction gas, and cleaning gas; the input pipeline assembly includes a first gas input pipeline and a second gas input pipeline; the first gas input pipeline is provided with gas injection holes; the second gas input pipeline is formed by an elbow joint and two single pipes; the second gas input pipeline is provided with gas injection holes.

### CROSS-REFERENCE TO RELATED APPLICATION

The present application claims priority to Chinese Patent Application No. 202111316125.1, filed on Nov. 8, 2021, the disclosure of which is hereby incorporated by reference in its entirety.

### BACKGROUND

In a related art, during preparation of a semiconductor device, a film is formed on a surface of a silicon substrate by an Atomic Layer Deposition (ALD) process. This process is to introduce reaction gases into a reaction chamber alternately, and produce a chemical reaction on a deposition surface to form a film. ALD process has good step-coverage performance and accurate control of single-layer film thickness. However, during forming the film, the introduced reaction gases often introduce impurities due to non-uniform distribution of the reaction gases, so that the film is formed non-uniformly, and a subsequent process effect is affected, thereby resulting in too large performance difference and low yield of the finally formed semiconductor devices.

### SUMMARY

The disclosure relates, but is not limited, to the technical field of semiconductor memories, and in particular, to a furnace and a method for forming a film.

The embodiment of the disclosure provides a furnace and a method for forming a film.

In a first aspect, the embodiment of the disclosure provides a furnace including a reaction chamber. A wafer boat assembly comprising multiple wafer boats each for bearing a substrate, and an input pipeline assembly configured to introduce a gas may be arranged in the reaction chamber.

The gas to be introduced may at least include: silicon-containing reaction gas, nitrogen-containing reaction gas, impurity removal reaction gas, and cleaning gas. The input pipeline assembly may include a first gas input pipeline and a second gas input pipeline arranged in a vertical direction.

The first gas input pipeline may be a single pipe provided with gas injection holes in the vertical direction. The first gas input pipeline may at least extend to the top and the bottom of the wafer boat assembly.

The second gas input pipeline may be a U-shaped or an inverted U-shaped pipeline formed by an elbow joint and two single pipes. The second gas input pipeline may at least extend to the top and the bottom of the wafer boat assembly. The single pipe of the two single pipes away from a gas inlet of the furnace may be provided with gas injection holes in the vertical direction.

In a second aspect, the embodiment of the disclosure provides a method for forming a film. The method may include the following operations.

Silicon-containing reaction gas may be introduced into a reaction chamber through a gas injection set, with the silicon-containing reaction gas being adsorbed by a surface of the substrate in the reaction chamber.

Nitrogen-containing reaction gas may be introduced into the reaction chamber through the input pipeline assembly to expose the adsorbed silicon-containing reaction gas to plasmas containing nitrogen free radical, to form a film layer on the substrate.

Before or after the introduction of the nitrogen-containing reaction gas, impurity removal reaction gas may be introduced into the reaction chamber to remove impurities introduced by the silicon-containing reaction gas.

At least said introductions of the silicon-containing reaction gas, the nitrogen-containing reaction gas, and the impurity removal reaction gas are repeated until the film layer formed on the substrate reaches a preset thickness.

### BRIEF DESCRIPTION OF THE DRAWINGS

In the drawings (which are not necessarily represented at a uniform scale), similar reference numerals may refer to similar parts in different views. Similar reference numerals with different letter suffixes may represent different examples of similar parts. The drawings generally illustrate the various embodiments discussed herein by way of examples rather than limitation.

FIG. 1A is a first schematic view of structure of a furnace provided by an embodiment of the disclosure.

FIG. 1B is a second schematic view of structure of a furnace provided by an embodiment of the disclosure.

FIG. 1C is a third schematic view of structure of a furnace provided by an embodiment of the disclosure.

FIG. 1D is a fourth schematic view of structure of a furnace provided by an embodiment of the disclosure.

FIG. 1E illustrates a schematic view of flow field distribution of hydrogen or ammonia in the furnace provided by the embodiment of the disclosure.

FIG. 1F illustrates another schematic view of a structure of the furnace provided by the embodiment of the disclosure.

FIG. 2 illustrates another schematic view of a composition structure of the furnace provided by the embodiment of the disclosure.

FIG. 3 illustrates a flowchart of a method for forming a film provided by the embodiment of the disclosure.

FIG. 4 illustrates another flowchart of the method for forming the film provided by the embodiment of the disclosure.

FIG. 5 illustrates another flowchart of the method for forming the film provided by the embodiment of the disclosure.

### DETAILED DESCRIPTION

Exemplary implementations disclosed by the disclosure will be described below more comprehensively with reference to the drawings. Although the exemplary implementation modes of the disclosure are shown in the drawings, it should be understood that, the disclosure may be implemented in various forms and should not be limited by the specific implementation modes elaborated herein. On the contrary, these implementation modes are provided to enable a more thorough understanding of the disclosure and to fully convey the scope of the disclosure to those skilled in the art.

In the following description, a large number of specific details are given in order to provide a more thorough understanding of the disclosure. However, it will be apparent to those skilled in the art that the disclosure may be implemented without one or more of these details. In other examples, in order to avoid confusion with the disclosure, some technical features known in the art are not described. That is, all the features of the actual embodiments are not described here, and the known functions and structures are not described in detail.

In the drawings, the dimensions of layers, areas, and elements and their relative dimensions may be exaggerated for clarity. Throughout, the same reference numerals represent the same elements.

It is to be understood that description that an element or layer is “above”, “adjacent to”, “connected to”, or “coupled to” another element or layer may refer to that the element or layer is directly above, adjacent to, connected to or coupled to the other element or layer, or there may be an intermediate element or layer. On the contrary, description that an element is “directly on”, “directly adjacent to”, “directly connected to” or “directly coupled to” another element or layer refers to that there is no intermediate element or layer. It is to be understood that, although various elements, components, areas, layers, and/or parts may be described with terms first, second, third, etc., these elements, components, areas, layers, and/or parts should not be limited to these terms. These terms are used only to distinguish one element, component, area, layer or part from another element, component, area, layer or part. Therefore, a first element, component, area, layer, or part discussed below may be represented as a second element, component, area, layer, or part without departing from the teaching of the disclosure. However, when the second element, component, area, layer, or part is discussed, it does not mean that the first element, component, area, layer, or part must exist in the disclosure.

The terms used herein are intended only to describe specific embodiments and are not a limitation of the disclosure. As used herein, singular forms “a/an”, “one”, and “the” may also be intended to include the plural forms, unless otherwise specified types in the context. It is also to be understood that, when terms “composed of” and/or “including” are used in this specification, the presence of the features, integers, steps, operations, elements, and/or components may be determined, but the presence or addition of one or more other features, integers, steps, operations, elements, components, and/or groups is also possible. As used herein, terms “and/or” includes any and all combinations of the related listed items.

A silicon nitride film plays an important role in preparation of integrated circuit devices. It can be used as a spacer layer, an etching barrier, a capacitor, an interlayer insulator, etc. A silicon nitride film process is also one of the important preparation processes. When the silicon nitride film is formed by an ALD process, SiH₂Cl₂ (DCS) is used as a precursor gas. However, during generating the silicon nitride by the DCS, chlorine will be generated, and a small amount of chlorine is deposited in the silicon nitride film. The chlorine will lead to the poor stability of a device and result in that a wet etching rate is too fast. The ALD process is in a batch reaction mode. However, the furnace cannot enable a reaction gas to be distributed uniformly, resulting in different concentrations of reaction gases in contact with a wafer boat at different positions, and non-uniform thickness of the silicon nitride film, which further causes the difference of the wet etching rate at different positions of the film. For example, for the silicon nitride on a side wall of a bit line, if the wet etching rate is too fast, it will require a thicker film thickness to resist leakage current. The increase in the thickness of the side wall of the bit line will lead to too small contact node area between two bit lines, which will cause the problem that the reading and writing speed of the device is slowed down. A problem to be solved is how to prepare the silicon nitride film which has the uniform thickness and contain only minute quantities of impurities through the ALD, and improve the process stability of the device.

The disclosure is further described in detail below with reference to the accompanying drawings specific embodiments.

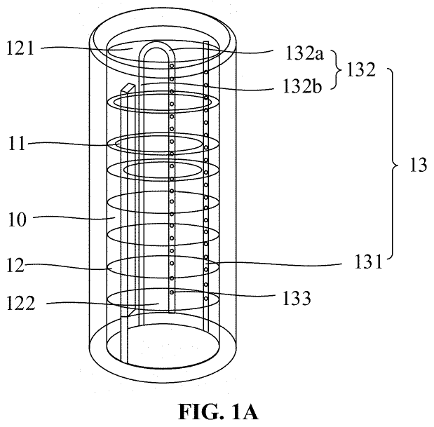

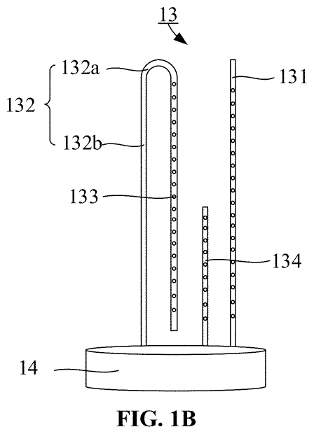

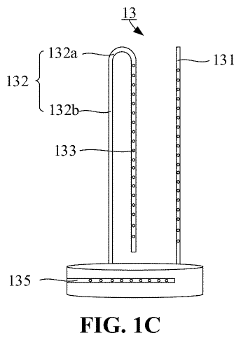

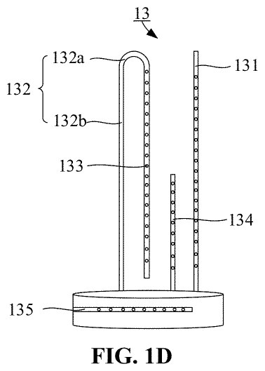

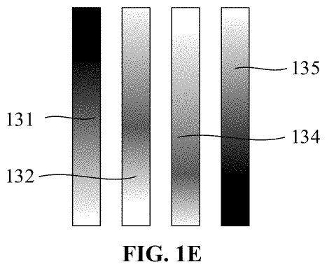

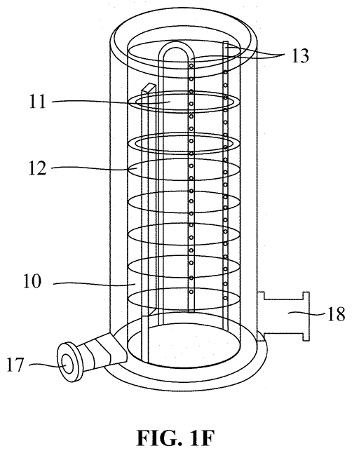

The embodiment of the disclosure provides a furnace, as shown in FIG. 1A, including a reaction chamber 10. A wafer boat assembly comprising multiple wafer boats 12 and an input pipeline assembly 13 configured to introduce a gas are arranged in the reaction chamber. A semiconductor substrate 11 or a wafer 11 is borne on the wafer boat.

The introduced gas at least includes: silicon-containing reaction gas, nitrogen-containing reaction gas, impurity removal reaction gas, and cleaning gas. The input pipeline assembly 13 includes a first gas input pipeline 131 and a second gas input pipeline 132 arranged in a vertical direction of the furnace.

The first gas input pipeline 131 is a single pipe provided with gas injection holes 133 arranged in the vertical direction. The first gas input pipeline 131 at least extends to the top 121 and the bottom 122 of the wafer boat assembly.

The second gas input pipeline 132 is a U-shaped or an inverted U-shaped pipeline formed by an elbow joint 132a and two single pipes 132b. The second gas input pipeline 132 at least extends to the top 121 and the bottom 122 of the wafer boat assembly. The single pipe of the two single pipes 132b away from a gas inlet of the furnace is provided with gas injection holes 133 arranged in the vertical direction.

Here, the furnace may be a batch-type vertical furnace, which can enable a plurality of substrates (also referred to as wafers or chips) to be supported on respective wafer boats in a multi-stage manner at predetermined intervals. The wafer boats may be quartz wafer boats. The reaction chamber may be cylindrical or in other shapes, and the wafer boat is located in the reaction chamber. During the depositing of forming the silicon nitride film or other films, the wafer boat may be driven to rotate by a rotating component, so that the silicon nitride grows on the substrate more uniformly, which further improves the uniformity of a silicon nitride film.

It is to be understood that the silicon-containing reaction gas may include at least one of Si₂H₂Cl₂ (DCS), Hexachlorodisilane (HCD), or the like. The nitrogen-containing reaction gas may include at least one of ammonia (NH₃), hydrazine (N₂H₄), or the like. The cleaning gas may be an inactive gas that does not react with the reaction gases or the silicon nitride, such as Argon (Ar), Nitrogen (N₂), Helium (He), Xenon (Xe), Neon (Ne), etc. The impurity removal reaction gas may be hydrogen, the impurity removal reaction gas is configured to remove the impurities introduced by the silicon-containing reaction gas, such as chlorine ions or chlorine free radicals introduced by the DCS, so as to combine to produce chlorine. The introduction of the impurity removal reaction gas can reduce HCl generated by the DCS and the ammonia, and reduce the erosion on the silicon nitride film which cause the non-uniformity of the silicon nitride film, thereby improving the stability of the device and alleviate the problem of too fast etching rate.

In some embodiments, the silicon-containing reaction gas may be replaced with a titanium-containing reaction gas, so that a titanium nitride film can be generated.

During implementing, the material of the first gas input pipeline may be a quartz material, and the material of the second gas input pipeline may also be a quartz material, or other high-temperature-resistant materials that do not react with the introduced gas.

In some embodiments, as shown in FIG. 1B, a base plate 14 for supporting the wafer boat is arranged in the reaction chamber. The first gas input pipeline 131 and the second gas input pipeline 132 are arranged at a side edge of the base plate 14. Thus, the first gas input pipeline and the second gas input pipeline can be stably fixed in the reaction chamber.

During implementing, gas injection holes of the first gas input pipeline and the second gas input pipeline may be designed according to actual requirements, which is not limited herein. For example, in the direction from the bottom to the top of the first gas input pipeline, the diameters of the gas injection holes are reduced in sequence. In the direction from one end of the second gas input pipeline adjacent to the gas inlet of the furnace to the other end away from the gas inlet of the furnace, the diameters of the gas injection holes are reduced in sequence. As such, each of the first gas input pipeline and the second gas input pipeline is provided with the gas injection holes with different diameters, which enables the gas to be distributed uniformly at the wafer boats at different positions in the reaction chamber.

In some embodiments, in the direction from the bottom to the top, the diameters of the gas injection holes of the first gas input pipeline are reduced in sequence. The diameter of the gas injection hole in an upper part of the first gas input pipeline is ⅓ to ⅔ times the diameter of the gas injection hole in a bottom part of the first gas input pipeline, and the diameter of the gas injection hole in a middle part of the first gas input pipeline is ¾ to ⅔ times the diameter of the gas injection hole in the bottom part.

In some embodiments, the diameters of the gas injection holes in the bottom are 1.0 mm, the diameters of the gas injection holes in the middle are 0.75 mm, and the diameters of the gas injection holes in the top are 0.5 mm. The gas injection holes with different diameters are formed in the gas input pipelines with different shapes, so that the gas is distributed on the substrate on the wafer boat more uniformly.

In the embodiment of the disclosure, gas input pipelines with different shapes are arranged, so that the gas is uniformly distributed on the substrate on the wafer boat, which improves the film uniformity of the surface of the substrate, so as to ensure that an etching process implemented on the film subsequently can maintain a uniform etching rate at different films and ensure the accuracy of device preparation.

In some embodiments, as shown in FIG. 1B, the input pipeline assembly 13 further includes a third gas input pipeline 134 arranged in the vertical direction.

The third gas input pipeline 134 is a single pipe provided with gas injection holes 133 arranged in the vertical direction, and the third gas input pipeline 134 at least extends to the bottom and the middle of the wafer boat assembly.

Here, the length of the third gas input pipeline may be half of the length of the first gas input pipeline. The top of the third gas input pipeline is located at the middle of the wafer boat, and the third gas input pipeline may be arranged between the first gas input pipeline and the second gas input pipeline.

In some embodiments, as shown in FIG. 1C, the input pipeline assembly 13 further includes a fourth gas input pipeline 135 arranged horizontally. The fourth gas input pipeline 135 is a single pipe provided with gas injection holes.

Here, the fourth gas input pipeline may be a short straight pipe arranged horizontally, and may be arranged at the edge of the base plate and adjacent to the second gas input pipeline. The fourth gas input pipeline may also be a curved pipe wound around the base plate, which is not limited herein.

In some embodiments, as shown in FIG. 1D, the input pipeline assembly 13 may include the first gas input pipeline 131, the second gas input pipeline 132, the third gas input pipeline 134, and the fourth gas input pipeline 135. Thus, the introduced reaction gas may be distributed on the substrate on the wafer boat more uniformly. In the case of the furnace as shown in FIG. 1D, the flow field distribution of ammonia or hydrogen in first gas input pipeline, the second gas input pipeline, the third gas input pipeline, and the fourth gas input pipeline is as shown in FIG. 1E. It can be seen that the concentration of the hydrogen or ammonia in the first gas input pipeline 131 is maximal in a top area of the furnace, and is gradually reduced from the top area to a bottom area of the furnace. The concentration of the hydrogen or ammonia in the second gas input pipeline 132 is maximal in a central area of the furnace, and is gradually reduced from the central area to the top area or the bottom area of the furnace. The concentration of the hydrogen or ammonia in the third gas input pipeline 134 is maximal in a lower area of the furnace, and is minimal in the top area. The concentration of the hydrogen or ammonia in the fourth gas input pipeline 135 is maximal in the bottom area of the furnace, and is gradually reduced from the bottom area of the furnace to the top area of the furnace.

In some embodiments, referring to FIG. 1F, the furnace further includes: a gas inlet pipe 17 and an exhaust pipe 18. The gas inlet pipe 17 is connected with input pipeline assembly 13, and is configured to at least introduce the silicon-containing reaction gas, the nitrogen-containing reaction gas, the impurity removal reaction gas, and the cleaning gas.

The exhaust pipe 18 is connected with the reaction chamber 10, and is at least configured to exhaust the cleaning gas, and the silicon-containing reaction gas, the nitrogen-containing reaction gas and the impurity removal reaction gas remaining after the reaction (i.e. the unreacted silicon-containing reaction gas, the unreacted nitrogen-containing reaction gas and the unreacted impurity removal reaction gas).

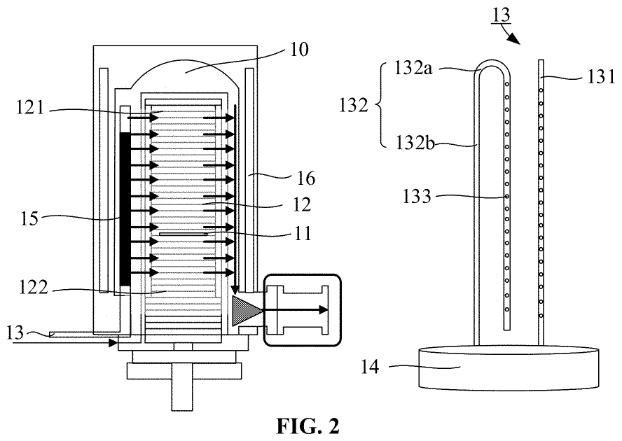

The embodiment of the disclosure provides a furnace. As shown in FIG. 2, a left figure illustrates a schematic plane view of a structure of a furnace, and a right figure illustrates a schematic view of a structure of an input pipeline assembly. The furnace includes a reaction chamber 10 in which a wafer boat 12 for bearing a substrate 11 and an input pipeline assembly 13 configured to introduce a gas are arranged.

The introduced gas at least includes silicon-containing reaction gas, nitrogen-containing reaction gas, impurity removal reaction gas and cleaning gas. The input pipeline assembly 13 includes a first gas input pipeline 131 and a second gas input pipeline 132 arranged in a vertical direction.

The first gas input pipeline 131 is a single pipe provided with gas injection holes 133 in the vertical direction. The first gas input pipeline 131 at least extends to the top 121 and the bottom 122 of the wafer boat assembly.

The second gas input pipeline 132 is a U-shaped or an inverted U-shaped pipeline formed by an elbow joint 132a and two single pipes 132b. The second gas input pipeline 132 at least extends to the top 121 and the bottom 122 of the wafer boat assembly. The single pipe of the two single pipes 132b away from a gas inlet of the furnace is provided with gas injection holes 133 in the vertical direction.

A radio frequency electrode 15 is arranged in the reaction chamber 10, and is configured to conduct free radical activation for the nitrogen-containing reaction gas and the impurity removal reaction gas introduced into the reaction chamber 10.

A heating component 16 is arranged to perform high-temperature tempering treatment on the substrate 11.

Here, the radio frequency electrode 15 conducts free radical activation for the nitrogen-containing reaction gas and the impurity removal reaction gas, which can reduce a load effect and improve the quality of the formed silicon nitride film. During implementing, the power of the radio frequency electrode may be 50 watts to 500 watts.

Here, the heating component 16 may be a heater. In order to heat more uniformly, the heater may include a plurality of sub-heaters, for example, five sub-heaters. The five sub-heaters are arranged to heat a top area, an upper area, a central area, a lower area and a bottom area of the reaction chamber respectively. During implementing, the heating component is further configured to maintain the temperature of the reaction chamber, so as to facilitate the reaction of the silicon-containing reaction gas with the nitrogen-containing reaction gas. The high-temperature tempering treatment may optimize a micro-structure of the silicon nitride film, so as to improve the density of the silicon nitride film, and solve the problem of too fast wet etching rate.

In some embodiments, the furnace further includes: a gas inlet pipe and an exhaust pipe. The gas inlet pipe is connected with the input pipeline assembly, and is at least configured to introduce the silicon-containing reaction gas, the nitrogen-containing reaction gas, the impurity removal reaction gas, and the cleaning gas.

The exhaust pipe is connected with the reaction chamber, and is at least configured to exhaust the cleaning gas, and the silicon-containing reaction gas, the nitrogen-containing reaction gas and the impurity removal reaction gas remaining after reaction.

In some embodiments, the furnace further includes: a valve arranged in the gas inlet pipe, and configured to adjust the pressure in the reaction chamber.

The pressure in the reaction chamber may be changed by adjusting the valve. In this way, the problem of non-uniform pressure distribution in the reaction chamber can be solved, the concentration difference of the reaction gas between different height positions of the reaction chamber can be reduced, and even the concentration of the reaction gas at different height positions of the reaction chamber can be the same. As such, the uniformity of the thicknesses of the nitride films generated at different height positions of the reaction chamber can be improved, and then the stability of a device can be improved.

In some embodiments, the furnace further includes a base plate arranged in the reaction chamber. The base plate is configured to support the wafer boat. The input pipeline assembly is arranged at a side edge of the base plate.

In some embodiments, the furnace further includes a mass flow controller arranged in the gas inlet pipe, and configured to control the mass of gas according to a type of the gas when the gas is introduced. In this way, the amount of the gas introduced into the reaction chamber can be precisely controlled to promote the rate of a reaction to form the silicon nitride.

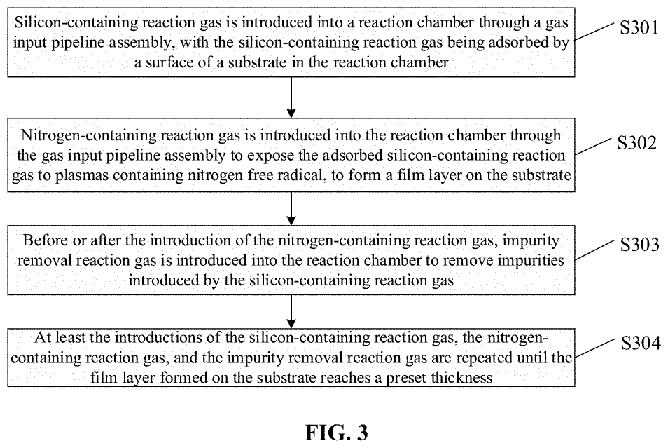

The embodiment of the disclosure provides a method for forming a film, as shown in FIG. 3, including the following operations.

At S301, silicon-containing reaction gas is introduced into a reaction chamber through a gas input pipeline assembly, and the silicon-containing reaction gas is adsorbed by a surface of a substrate in the reaction chamber.

Here, in order to enable the introduced reaction gas to be distributed more uniformly, the input pipeline assembly may be an input pipeline assembly in the furnace provided by the disclosure. For example, the input pipeline assembly 13 as shown in FIG. 1A includes a first gas input pipeline 131 and a second gas input pipeline 132 arranged in the vertical direction. The first gas input pipeline 131 is a single pipe provided with gas injection holes 133 in the vertical direction, and the first gas input pipeline 131 at least extends to a top 121 and a bottom 122 of a wafer boat assembly. The second gas input pipeline 132 is a U-shaped or an inverted U-shaped pipeline formed by an elbow joint 132a and two single pipes 132b, and the second gas input pipeline 132 at least extends to the top 121 and the bottom 122 of the wafer boat assembly. The single pipe of the two single pipes 132b away from a gas inlet of the furnace is provided with gas injection holes 133 in the vertical direction. In some embodiments, the input pipeline assembly as shown in FIG. 1B, FIG. 1C, or FIG. 1D may also be used.

Here, the substrate may be a silicon substrate, a germanium substrate, a silicon germanium substrate, a group III-IV substrate, a silicon carbide substrate or a silicon dioxide layer, etc., and may also be a groove structure such as a trench or a deep hole formed in the above-mentioned substrate, or other structures on which a silicon nitride film to be formed, such as a substrate where a bit line side wall structure is to be formed, and a substrate where an etching barrier layer, an interlayer insulator or a spacer layer is to be formed. The silicon-containing reaction gas will be adsorbed by the substrate, and the adsorption will be stopped when the adsorption of the surface of the substrate is saturated.

The pressure of the reaction chamber is adjusted to be 1 torr to 10 torr, for example, 7 torr, when the silicon-containing reaction gas is introduced. The flow rate of the silicon-containing gas may be 2 slm (liters per minute under standard conditions).

At S302, nitrogen-containing reaction gas is introduced into the reaction chamber through the input pipeline assembly to expose the adsorbed silicon-containing reaction gas to plasmas containing nitrogen free radical, to form a film layer on the substrate by the adsorbed silicon-containing reaction gas.

Here, the silicon-containing reaction gas will react with the plasmas containing nitrogen free radical to form a silicon nitride film layer on the substrate. The plasmas containing nitrogen free radical may be generated outside the reaction chamber by a remote plasma process, and then is introduced into a reaction area in the reaction chamber by a gas flow, an electric field or a magnetic field, etc. A radio frequency electrode may also be arranged in the reaction chamber. After the nitrogen-containing reaction gas is introduced into the reaction chamber through the input pipeline assembly, the nitrogen-containing reaction gas is activated to produce the plasmas containing nitrogen free radical in the reaction area of the reaction chamber by the radio frequency electrode.

At S303, before or after the introduction of the nitrogen-containing reaction gas, impurity removal reaction gas is introduced into the reaction chamber to remove impurities introduced by the silicon-containing reaction gas.

Here, S303 in combination with S301 and S302, may include the following two cases.

Case 1): silicon-containing reaction gas, nitrogen-containing reaction gas and impurity removal reaction gas are sequentially introduced into the reaction chamber; and

Case 2): silicon-containing reaction gas, impurity removal reaction gas and nitrogen-containing reaction gas are sequentially introduced into the reaction chamber.

In case 1), the impurity removal reaction gas is introduced after the nitrogen-containing reaction gas, and in case 2) the impurity removal reaction gas is introduced before the nitrogen-containing reaction gas.

Here, the impurity removal reaction gas may be introduced into the reaction chamber before the introduction of the nitrogen-containing reaction gas, so as to remove the impurities introduced by the silicon-containing reaction gas. In this case, the impurity removal reaction gas is hydrogen, and the impurities may be chloride ions. Hydrogen and the chloride ions form hydrogen chloride, so as to remove the impurities introduced by the silicon-containing reaction gas. The impurity removal reaction gas may also be introduced into the reaction chamber after the introduction of the nitrogen-containing reaction gas, so as to remove the impurities introduced by the silicon-containing reaction gas.

When the impurity removal reaction gas is introduced, the pressure of the reaction chamber is adjusted to be 0.1 torr to 1 torr, for example, 0.5 torr, and the flow rate of the impurity removal reaction gas may be 3 slm.

At S304, at least the operations of introducing the silicon-containing reaction gas, the nitrogen-containing reaction gas and the impurity removal reaction gas are repeated cyclically until the film layer formed on the substrate reaches a preset thickness.

Here, the preset thickness is determined according to actual requirements. The thickness of the formed silicon nitride film can be adjusted by adjusting the number of the repeat.

In the embodiment of the disclosure, the impurity removal reaction gas is introduced into the reaction chamber before or after the introduction of the nitrogen-containing reaction gas, so as to remove the impurities introduced by the silicon-containing reaction gas, thereby improving the density of the formed silicon nitride film, and solving the problem of too fast wet etching rate. Then, leakage current can be resisted in the case that a bit line side wall with a relatively thin thickness is formed, so as to increase a contact area of a contact node and improve the stability and the reading and writing speed of the device.

In some embodiments, the method further includes the following operation: free radical activation is conducted for the nitrogen reaction gas and the impurity removal reaction gas when the nitrogen-containing reaction gas and the impurity removal reaction gas are introduced into the reaction chamber.

Here, the free radical activation may be conducted for the nitrogen-containing reaction gas and the impurity removal reaction gas in the same way. For example, plasmas containing nitrogen free radical may be generated outside the reaction chamber by a remote plasma process, and then is introduced into a reaction area in the reaction chamber by gas flow, an electric field or a magnetic field, etc. A radio frequency electrode may also be arranged in the reaction chamber. After the nitrogen-containing reaction gas and the impurity removal reaction gas are introduced into the reaction chamber through the input pipeline assembly, the nitrogen-containing reaction gas and the impurity removal reaction gas are activated to produce the plasmas containing nitrogen free radical and impurity removal reaction gas-containing plasmas in the reaction area of the reaction chamber by the radio frequency electrode.

In some embodiments, the method further includes: at S305, before or after the silicon-containing reaction gas is introduced, before or after the nitrogen-containing reaction gas is introduced, and before or after the impurity removal reaction gas is introduced, the cleaning gas is introduced into the reaction chamber through the input pipeline assembly, so as to clean the reaction chamber.

In order to reduce the influence of a previous reaction gas on a following reaction process, the cleaning gas is introduced between the two reaction processes for cleaning. Here, S305 in combination with S303 may include at least the following cases.

Case 1), cleaning gas, silicon-containing reaction gas, cleaning gas, nitrogen-containing reaction gas, cleaning gas and impurity removal reaction gas are sequentially introduced into the reaction chamber.

Case 2), cleaning gas, silicon-containing reaction gas, cleaning gas, impurity removal reaction gas, cleaning gas and nitrogen-containing reaction gas are sequentially introduced into the reaction chamber.

In the embodiments of the disclosure, unreacted silicon-containing reaction gas, nitrogen-containing reaction gas and impurity removal reaction gas may be removed by introducing the cleaning gas, and the impurities on the substrate may also be removed, so as to improve the quality of the silicon nitride film.

In some embodiments, the silicon-containing reaction gas is Si₂H₂Cl₂. The nitrogen-containing reaction gas is ammonia, or a mixed gas of ammonia and hydrogen. The impurity removal reaction gas is hydrogen. The cleaning gas includes nitrogen.

The operation of repeating the introduction of the silicon-containing reaction gas, the nitrogen-containing reaction gas, and the impurity removal reaction gas includes repeating one of the following four processes.

Process 1: nitrogen, Si₂H₂Cl₂, nitrogen, ammonia, nitrogen, and hydrogen are introduced into the reaction chamber in sequence.

Process 2: nitrogen, Si₂H₂Cl₂, nitrogen, hydrogen, nitrogen, and ammonia are introduced into the reaction chamber in sequence.

Process 3: nitrogen, Si₂H₂Cl₂, nitrogen, hydrogen, nitrogen, and a mixed gas of ammonia and hydrogen are introduced into the reaction chamber in sequence.

Process 4: nitrogen, Si₂H₂Cl₂, nitrogen, a mixed gas of ammonia and hydrogen, nitrogen, and hydrogen are introduced into the reaction chamber in sequence.

In the above four processes, by setting the introduction sequence of the impurity removal reaction gas and the nitrogen-containing reaction gas, the impurity Cl introduced by the Si₂H₂Cl₂ can be effectively removed, and Cl atoms and the C₁₂ are prevented from depositing in the silicon nitride film, so that the deposition quality of the silicon nitride film is improved.

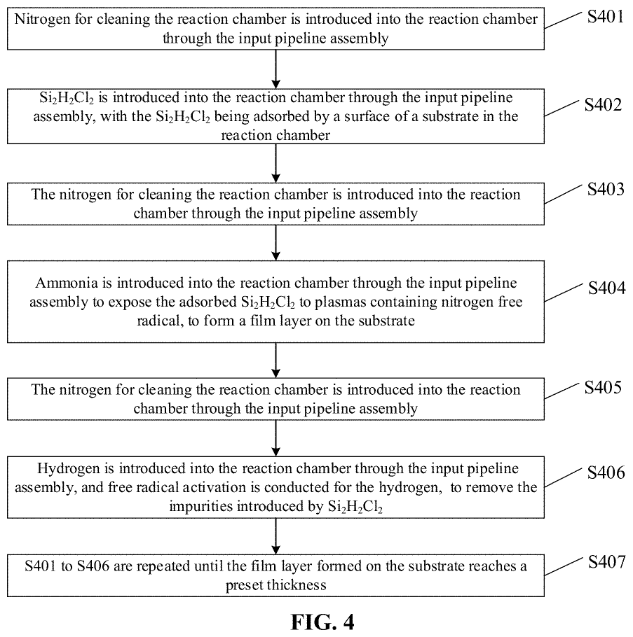

The embodiment of the disclosure provides a method for forming a film based on the above-mentioned process 1, as shown in FIG. 4, including the following operations.

At S401, nitrogen for cleaning the reaction chamber is introduced into the reaction chamber through the input pipeline assembly.

At S402, Si₂H₂Cl₂ is introduced into the reaction chamber through the input pipeline assembly, the Si₂H₂Cl₂ is adsorbed by a surface of a substrate in the reaction chamber.

At S403, the nitrogen for cleaning the reaction chamber is introduced into the reaction chamber through the input pipeline assembly.

At S404, ammonia is introduced into the reaction chamber through the input pipeline assembly to expose the adsorbed Si₂H₂Cl₂ to plasmas containing nitrogen free radical, to form a film layer on the substrate.

Here, in process 1, ammonia serves as a reaction gas.

In another embodiment, the nitrogen-containing reaction gas may also be a mixed gas of ammonia and hydrogen, as the case in the process 4.

At S405, nitrogen for cleaning the reaction chamber is introduced into the reaction chamber through the input pipeline assembly.

At S406, hydrogen is introduced into the reaction chamber through the input pipeline assembly, and free radical activation is conducted for the hydrogen, to remove the impurities introduced by Si₂H₂Cl₂.

At S407, S401 to S406 are repeated until the film layer formed on the substrate reaches a preset thickness.

Here, in S401 to S406, the temperature in the reaction chamber is maintained between 350° C. and 650° C. The flow rate of the nitrogen in S401 may be 5 slm, so as to maximize the cleaning of the impurities in the reaction chamber. The flow rate of the nitrogen in S403 and S405 may be 2 slm, and may also be selected according to actual requirements, which is not limited herein.

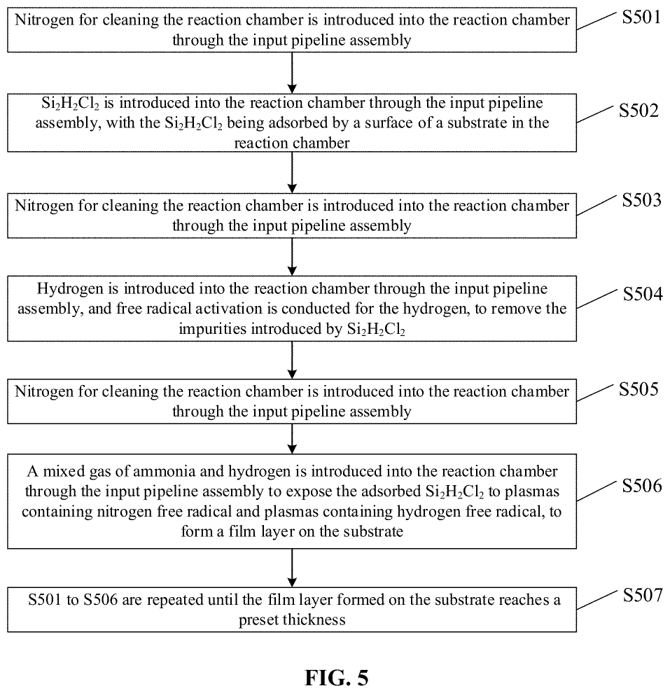

The embodiment of the disclosure also provides a method for forming a film based on the above-mentioned process 3, as shown in FIG. 5, including the following operations.

The specific implementations of S501 to S503 are described as the S401 to S403 set forth above, and the detailed description thereof will be omitted.

At S504, hydrogen is introduced into the reaction chamber through the input pipeline assembly, and free radical activation is conducted for the hydrogen, to remove the impurities introduced by Si₂H₂Cl₂.

At S505, nitrogen for cleaning the reaction chamber is introduced into the reaction chamber through the input pipeline assembly.

At S506, a mixed gas of ammonia and hydrogen is introduced into the reaction chamber through the input pipeline assembly to expose the adsorbed Si₂H₂Cl₂ to plasmas containing nitrogen free radical and plasmas containing hydrogen free radical, to form a film layer on the substrate.

Here, in process 3, the mixed gas of ammonia and hydrogen serves as a reaction gas. In another embodiment, the nitrogen-containing reaction gas may also be ammonia, as the case in the process 2.

At S507, S501 to S506 are repeated until the film layer formed on the substrate reaches a preset thickness.

In some embodiments, the input pipeline assembly controls the gas introduced into the reaction chamber to be distributed uniformly through a first gas input pipeline and a second gas input pipeline.

The first gas input pipeline is a single pipe provided with gas injection holes in the vertical direction.

The second gas input pipeline is a U-shaped or an inverted U-shaped pipeline formed by an elbow joint and two single pipes. The single pipe of the two single pipes away from a gas inlet of the furnace is provided with gas injection holes in the vertical direction. The input pipeline assembly controls the gas introduced into the reaction chamber to be distributed uniformly through the first gas input pipeline and the second gas input pipeline, which can improve the gas distribution on the substrates on the wafer boats at different positions in the reaction chamber, thereby improving the stability of the silicon nitride film.

In some embodiments, the pressure in the reaction chamber is adjusted when the gas is introduced into the reaction chamber. The pressure in the reaction chamber is adjusted by adjusting the opening degree of a valve of an inlet pipe connected to the reaction chamber. Different opening degrees of the valve may correspond to different gas introducing amounts. Thus, the introduced gas can be uniformly distributed on the substrates on the wafer boats at different positions.

In some embodiments, when cleaning gas is introduced into the reaction chamber, the opening degree of the valve is adjusted to be 90% to 100%, for example, 100%. When silicon-containing reaction gas is introduced into the reaction chamber, the opening degree of the valve is adjusted to be 5% to 7%, for example, 5%. When nitrogen-containing reaction gas and impurity removal reaction gas are introduced into the reaction chamber, the opening degree of the valve is adjusted to be 10%.

In some embodiments, the method further includes a high-temperature tempering treatment process. The high-temperature tempering treatment process is performed after a film layer on the substrate reaches the preset thickness.

In the high-temperature tempering treatment process, a protective gas is introduced into the reaction chamber, the temperature of the reaction chamber is adjusted to be between 550° C. and 800° C., the pressure of the reaction chamber is adjusted to be between 0.1 torr and 1 torr, and the flow rate of the protective gas is adjusted to be between 0.5 slm and 5 slm. The protective gas includes hydrogen, and free radical activation is conducted when the protective gas is introduced into the reaction chamber. The density of the formed silicon nitride film layer may be improved through the high temperature tempering treatment, thus, the problem of too fast wet etching rate can be further solved. The protective gas may be hydrogen or a combination of hydrogen and ammonia.

In some embodiments, during the high-temperature tempering treatment, the temperature of the reaction chamber is 630° C., and the pressure of the reaction chamber is 0.5 torr. The protective gas is hydrogen, and the flow rate of the hydrogen is 3 slm.

In several embodiments provided by the disclosure, it is to be understood that the disclosed device and method may be implemented in a non-target manner. The device embodiment described above is only schematic, and for example, division of the units is only logic function division, and other division manners may be adopted during practical implementation. For example, a plurality of units or components may be combined or integrated into another system, or some characteristics may be neglected or not executed. In addition, the components shown or discussed are coupled to each other, or directly coupled.

The above-mentioned units described as separate parts may be or may not be physically separate, and the parts shown as units may be or may not be physical elements, which may be located in one place or distributed to a plurality of network elements. Part or all of the units may be selected to achieve the objectives of the solutions of the embodiments according to practical requirements.

The characteristics disclosed in several method or device embodiments provided in the disclosure may be freely combined without conflicts to obtain new method embodiments or device embodiments.

The above are only some implementation modes of the embodiments of the disclosure and not intended to limit the scope of protection of the embodiment of the disclosure. Modifications or replacements readily figured out by those skilled in the art within the technical scope disclosed by the embodiments of the disclosure shall fall within the scope of protection of the embodiment of the disclosure. Therefore, the scope of protection of the embodiments of the disclosure shall be subject to the scope of protection of the claims.

What is claimed is:

1. A furnace comprising a reaction chamber, wherein a wafer boat assembly comprising multiple wafer boats each for bearing a substrate and an input pipeline assembly configured to introduce a gas are arranged in the reaction chamber;
the gas to be introduced at least comprises: silicon-containing reaction gas, nitrogen-containing reaction gas, impurity removal reaction gas and cleaning gas; the input pipeline assembly comprises a first gas input pipeline and a second gas input pipeline arranged in a vertical direction;
the first gas input pipeline is a single pipe provided with gas injection holes arranged in the vertical direction; the first gas input pipeline at least extends to a top and a bottom of the wafer boat assembly;
the second gas input pipeline is a U-shaped or inverted U-shaped pipeline formed by an elbow joint and two single pipes; the second gas input pipeline at least extends to the top and the bottom of the wafer boat assembly; and the single pipe of the two single pipes away from a gas inlet of the furnace is provided with gas injection holes arranged in the vertical direction.

2. The furnace according to claim 1, wherein the input pipeline assembly further comprises a third gas input pipeline arranged in the vertical direction;
the third gas input pipeline is a single pipe provided with gas injection holes in the vertical direction; and the third gas input pipeline at least extends to the bottom and the middle of the wafer boat assembly.

3. The furnace according to claim 1, wherein the input pipeline assembly further comprises a fourth gas input pipeline horizontally arranged; and the fourth gas input pipeline is a single pipe provided with gas injection holes.

4. The furnace according to claim 1, wherein the gas injection holes of at least one of the first gas input pipeline and the second gas input pipeline are configured in such a way that:
in the direction from the bottom to the top, the diameters of the gas injection holes are reduced in sequence, or
in the direction from one end adjacent to the gas inlet of the furnace to the other end away from the gas inlet of the furnace, the diameters of the gas injection holes are reduced in sequence.

5. The furnace according to claim 4, wherein in the direction from the bottom to the top, the diameters of the gas injection holes of the first gas input pipeline are reduced in sequence, the diameter of the gas injection holes in an upper part of the first gas input pipeline is ⅓ to ⅔ times the diameter of the gas injection holes in a bottom part of the first gas input pipeline, and the diameter of the gas injection holes in a middle part of the first gas input pipeline is ¾ to ⅔ times the diameter of the gas injection holes in the bottom part.

6. The furnace according to claim 4, further comprising: a radio frequency electrode and a heating component arranged in the reaction chamber, wherein
the radio frequency electrode is configured to conduct free radical activation for the nitrogen-containing reaction gas and the impurity removal reaction gas introduced into the reaction chamber; and
the heating component is configured to perform high-temperature tempering treatment on a substrate.

7. The furnace according to claim 1, further comprising:
a gas inlet pipe connected with the reaction chamber, wherein the gas inlet pipe is configured to at least introduce the silicon-containing reaction gas, the nitrogen-containing reaction gas, the impurity removal reaction gas and the cleaning gas; and
an exhaust pipe connected with the reaction chamber, wherein the exhaust pipe is configured to at least exhaust the cleaning gas and the silicon-containing reaction gas, the nitrogen-containing reaction gas, and the impurity removal reaction gas remaining after reaction.

8. The furnace according to claim 7, further comprising a valve arranged in the gas inlet pipe, and configured to adjust the pressure in the reaction chamber.

9. The furnace according to claim 1, further comprising a base plate arranged in the reaction chamber; the base plate is configured to support the wafer boats;
the input pipeline assembly is arranged at a side edge of the base plate.

10. The furnace according to claim 8, further comprising a mass flow controller, arranged in the gas inlet pipe, and configured to control the mass of gas according to a type of the gas when the gas is introduced.

11. A method for forming a film, comprising:
introducing silicon-containing reaction gas into a reaction chamber through an input pipeline assembly, with the silicon-containing reaction gas being adsorbed by a surface of a substrate in the reaction chamber;
introducing nitrogen-containing reaction gas into the reaction chamber through the input pipeline assembly to expose the adsorbed silicon-containing reaction gas to plasmas containing nitrogen free radical, to form a film layer on the substrate;
before or after the introduction of the nitrogen-containing reaction gas, introducing impurity removal reaction gas into the reaction chamber to remove impurities introduced by the silicon-containing reaction gas; and
repeating at least said introductions of the silicon-containing reaction gas, the nitrogen-containing reaction gas and the impurity removal reaction gas until the film layer formed on the substrate reaches a preset thickness.

12. The method according to claim 11, further comprising:
conducting free radical activation for the nitrogen reaction gas and the impurity removal reaction gas respectively when the nitrogen-containing reaction gas and the impurity removal reaction gas are introduced into the reaction chamber.

13. The method according to claim 11, further comprising:
before or after the introduction of the silicon-containing reaction gas, introducing a cleaning gas for cleaning the reaction chamber into the reaction chamber through the input pipeline assembly;
before or after the introduction of the nitrogen-containing reaction gas, introducing the cleaning gas for cleaning the reaction chamber into the reaction chamber through the input pipeline assembly; and
before or after the introduction of the impurity removal reaction gas, introducing the cleaning gas for cleaning the reaction chamber into the reaction chamber through the input pipeline assembly.

14. The method according to claim 13, wherein the silicon-containing reaction gas is Si₂H₂Cl₂;
the nitrogen-containing gas is ammonia or a mixed gas of ammonia and hydrogen;
the impurity removal reaction gas is hydrogen; and
the cleaning gas comprises nitrogen.

15. The method according to claim 14, wherein the repeating at least the introductions of the silicon-containing reaction gas, the nitrogen-containing reaction gas and the impurity removal reaction gas comprises:repeating one of the following processes:
a process of introducing nitrogen, Si₂H₂Cl₂, nitrogen, ammonia, nitrogen and hydrogen in sequence;
a process of introducing nitrogen, Si₂H₂Cl₂, nitrogen, hydrogen, nitrogen and ammonia in sequence;
a process of introducing nitrogen, Si₂H₂Cl₂, nitrogen, hydrogen, nitrogen, and a mixed gas of ammonia and hydrogen in sequence; and
a process of introducing nitrogen, Si₂H₂Cl₂, nitrogen, hydrogen, nitrogen, and a mixed gas of ammonia and hydrogen in sequence.

16. The method according to claim 12, further comprising:
when the gas is introduced into the reaction chamber, adjusting the pressure in the reaction chamber by adjusting an opening degree of a valve of a gas inlet pipe connected to the reaction chamber.

17. The method according to claim 16, wherein the adjusting the pressure in the reaction chamber by adjusting the opening degree of the valve comprises:
adjusting the opening degree of the valve to be between 90% and 100% when the cleaning gas is introduced into the reaction chamber;
adjusting the opening degree of the valve to be between 5% and 7% when the silicon-containing reaction gas is introduced into the reaction chamber; and
adjusting the opening degree of the valve to be 10% when each of the nitrogen-containing reaction gas and impurity removal reaction gas is introduced into the reaction chamber.

18. The method according to claim 13, further comprising a high-temperature tempering treatment process, wherein the high-temperature tempering treatment process is performed after the film layer on the substrate reaches the preset thickness;
the high-temperature tempering treatment process comprises:
introducing a protective gas into the reaction chamber,
adjusting the temperature of the reaction chamber to be between 550° C. and 800° C.,
adjusting the pressure in the reaction chamber to be between 0.1 torr and 1 torr, and
controlling the flow rate of the protective gas to be between 0.5 slm and 5 slm;
the protective gas comprises hydrogen, and the protective gas is subjected with free radical activation when being introduced into the reaction chamber.

19. The method according to claim 13, wherein
the input pipeline assembly controls the gases introduced into the reaction chamber to be distributed uniformly through a first gas input pipeline and a second gas input pipeline;
the first gas input pipeline is a single pipe provided with gas injection holes from in a vertical direction;
the second gas input pipeline is a U-shaped or an inverted U-shaped pipeline formed by an elbow joint and two single pipes; and the single pipe of the two single pipes away from a gas inlet of the furnace is provided with gas injection holes in the vertical direction.

20. The method according to claim 11, further comprising:
adjusting the pressure in the reaction chamber to be between 1 torr and 10 torr when the silicon-containing reaction gas is introduced into the reaction chamber; and
adjusting the pressure in the reaction chamber to be between 0.1 torr and 1 torr when the nitrogen-containing reaction gas or the impurity removal reaction gas is introduced into the reaction chamber.
